(19) United States
(12) Patent Application Publication
(10) Pub. No.: US 2026/0282835 A1
(43) Pub. Date: Sep. 17, 2026

(54) SEMICONDUCTOR CHIP PROTECT FILM

(71) Applicant: Samsung Electronics Co., Ltd., Suwon-si (KR)

(72) Inventors: Du Sik Jung, Suwon-si (KR); Yun Seok Choi, Suwon-si (KR)

(73) Assignee: Samsung Electronics Co., Ltd., Suwon-si (KR)

(21) Appl. No.: 19/419,697

(22) Filed: Dec. 15, 2025

(30) Foreign Application Priority Data
Mar. 14, 2025 (KR) 10-2025-0033143

(51) Int. Cl. H10P 72/70; H10F 39/00; H10F 39/18; H10W 46/00

(52) U.S. Cl. CPC H10P 72/7408; H10F 39/182; H10F 39/811; H10W 46/301

(57) ABSTRACT

A semiconductor chip protection film is provided. A semiconductor chip protection film comprises a plurality of sub-films which are attached to a wafer; and a carrier which carries the plurality of sub-films, wherein at least one of the sub-films and the carrier includes a film alignment mark on an upper side, the wafer has a die alignment mark on an upper side, the sub-films are attached at a first position on the wafer, and the first position is a position at which the film alignment mark and the die alignment mark overlap in a first direction.

### CROSS-REFERENCE TO RELATED APPLICATION

This present application claims priority to and the benefit under 35 U.S.C. § 119(a)-(d) of Korean Patent Application No. 10-2025-0033143 filed on Mar. 14, 2025, in the Korean Intellectual Property Office, the entire disclosure of which is incorporated herein by reference.

### BACKGROUND

The present disclosure relates to a semiconductor chip protection film.

An image sensor element is a semiconductor element equipped with an integrated circuit including tens of millions of pixels that convert a light energy into an electrical signal. For example, in a CMOS image sensor, most of a chip area is an active region for image sensing. Therefore, unlike other semiconductor devices, the process factors that occur when performing a fabricating process are closely related to a quality. One of the main causes of defects in the image sensor elements is silicon (Si) dusts generated in a wafer sawing process. Therefore, it is required to protect the active region of the image sensor in the process step.

### SUMMARY

Aspects of the present disclosure provide a semiconductor chip protection film for a semiconductor package having improved performance and yield.

According to aspects of the present disclosure, there is provided a semiconductor chip protection film comprising: a plurality of sub-films which are attached to a wafer; and a carrier which carries the plurality of sub-films, wherein at least one of the sub-films and the carrier includes a film alignment mark on an upper side, the wafer has a die alignment mark on an upper side, the sub-films are attached at a first position on the wafer, and the first position is a position at which the film alignment mark and the die alignment mark overlap in a first direction.

According to embodiments of the present disclosure, there is provided a semiconductor chip protection film which is attached to a semiconductor chip, and includes a film alignment mark on an upper side, wherein the semiconductor chip has a die alignment mark on an upper side, and the film alignment mark and the die alignment mark overlap in a first direction.

According to embodiments of the present disclosure, there is provided a semiconductor chip protection film comprising: a plurality of sub-films which are attached to a wafer including a plurality of semiconductor chips; and a carrier which carries the plurality of sub-films, wherein the carrier includes a film alignment mark on an upper side, the wafer has a die alignment mark on an upper side, and the film alignment mark and the die alignment mark overlap in the first direction.

According to aspects of the present disclosure, there is provided a method for fabricating a semiconductor package, the method comprising: providing a wafer which includes a plurality of semiconductor chips and a scribe lane for separating the semiconductor chips, and a semiconductor chip protection film which includes a plurality of sub-films attached to the semiconductor chips and a carrier for transporting the sub-films; and attaching a semiconductor chip protection film to the semiconductor chip, wherein the wafer has a die alignment mark on an upper side, the semiconductor chip protection film has a film alignment mark on an upper side, and the die alignment mark and the film alignment mark overlap in a first direction.

According to embodiments of the present disclosure, there is provided the method for fabricating the semiconductor package, the method further comprising, removing the carrier from the sub-films; and removing the scribe lane.

According to embodiments of the present disclosure, there is provided the method for fabricating the semiconductor package, the method further comprising, removing the carrier from the sub-films; and removing the scribe lane.

According to embodiments of the present disclosure, there is provided the method for fabricating the semiconductor package, the method further comprising, mounting a semiconductor chip unit on a substrate, the semiconductor chip unit including a semiconductor chip with the semiconductor chip protection film attached to an upper side and electrically connecting the semiconductor chip unit to the substrate through a wire.

According to embodiments of the present disclosure, there is provided the method for fabricating the semiconductor, the method further comprising, removing the semiconductor chip protection film.

According to embodiments of the present disclosure, there is provided the method for fabricating the semiconductor package, the method further comprising, disposing a cover glass on the semiconductor chip and filling a sealing material that seals the substrate, the semiconductor chip, and the cover glass.

According to embodiments of the present disclosure, there is provided the method for fabricating the semiconductor package, wherein an area of the sub-film is smaller than or equal to an area of the semiconductor chip.

According to embodiments of the present disclosure, there is provided the method for fabricating the semiconductor package, wherein the semiconductor chip includes a sensor region and a pad region that surrounds the sensor region, and in which a plurality of bonding pads for connecting the semiconductor chip to the outside are disposed, wherein the sub-film covers the sensor region, and an area of the sub-film is greater than or equal to an area of the sensor region.

According to embodiments of the present disclosure, there is provided the method for fabricating the semiconductor package, wherein the sensor region includes an active pixel sensor.

According to embodiments of the present disclosure, there is provided the method for fabricating the semiconductor package, wherein the die alignment mark is included on the pad region, and the film alignment mark is included on the sub-film.

According to embodiments of the present disclosure, there is provided the method for fabricating the semiconductor package, wherein the film alignment mark is disposed on the carrier.

According to embodiments of the present disclosure, there is provided the method for fabricating the semiconductor package, wherein the die alignment mark is disposed along an outer periphery of the wafer.

According to embodiments of the present disclosure, there is provided the method for fabricating the semiconductor package, wherein the die alignment mark is disposed between the plurality of semiconductor chips.

According to embodiments of the present disclosure, there is provided a method for fabricating a semiconductor package, the method comprising, providing a semiconductor chip including a die alignment mark, and a semiconductor chip protection film including a film alignment mark and attaching the semiconductor chip protection film to the semiconductor chip, wherein the die alignment mark and the film alignment mark overlap in a first direction.

According to embodiments of the present disclosure, there is provided the method for fabricating the semiconductor package, the method further comprising, removing a scribe lane disposed between the semiconductor chips.

According to embodiments of the present disclosure, there is provided the method for fabricating the semiconductor package, wherein the semiconductor chip includes a sensor region, and a pad region which surrounds the sensor region, and in which a plurality of bonding pads for connecting the semiconductor chip to the outside are disposed, wherein the semiconductor chip protection film is attached to the sensor region, and an area of the semiconductor chip protection film is smaller than or equal to an area of the semiconductor chip, and greater than or equal to an area of the sensor region.

According to embodiments of the present disclosure, there is provided the method for fabricating the semiconductor package, wherein the die alignment mark is included on the pad region.

According to embodiments of the present disclosure, there is provided the method for fabricating the semiconductor package, the method further comprising, mounting a semiconductor chip unit on a substrate, the semiconductor chip unit including a semiconductor chip with the semiconductor chip protection film attached to an upper side thereof and electrically connecting the semiconductor chip unit to the substrate through a wire.

According to embodiments of the present disclosure, there is provided the method for fabricating the semiconductor package, the method further comprising, removing the semiconductor chip protection film, disposing a cover glass on the semiconductor chip and filling a sealing material that seals the substrate, the semiconductor chip, and the cover glass.

According to embodiments of the present disclosure, there is provided a method for fabricating a semiconductor package, the method comprising, providing a wafer including a plurality of semiconductor chips, and a semiconductor chip protection film that includes a plurality of sub-films attached to the semiconductor chips and a carrier that carries the sub-films, attaching the semiconductor chip protection film to the semiconductor chip and removing the carrier from the sub-films, wherein the wafer has a die alignment mark on an upper side, the carrier includes a film alignment mark on an upper side, and the die alignment mark and the film alignment mark overlap in a first direction.

According to embodiments of the present disclosure, there is provided the method for fabricating the semiconductor package, the method further comprising, mounting a semiconductor chip unit on a substrate, electrically connecting the semiconductor chip unit to the substrate through a wire, removing the semiconductor chip protection film, disposing a cover glass on the semiconductor chip; and filling a sealing material that seals the substrate, the semiconductor chip, and the cover glass, wherein the semiconductor chip unit includes a semiconductor chip with the semiconductor chip protection film attached to an upper side.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

Specific embodiments are included in the detailed description and drawings.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a top view showing a wafer including a semiconductor chip according to some embodiments of the technical ideas of the present disclosure.

FIG. 2 is a top view showing a semiconductor chip protection film according to some embodiments of the technical ideas of the present disclosure.

FIG. 3 is a cross-sectional view showing cross sections along I-I′ and II-II′ together to explain the semiconductor chip protection film and wafer of FIGS. 1 and 2.

FIG. 4 is a top view showing only the semiconductor chip included in the die region of FIG. 2.

FIG. 5 is a top view showing only the semiconductor chip protection film included in the film region of FIG. 1.

FIGS. 6 to 8 are cross-sectional views for explaining a method for fabricating a semiconductor chip unit according to some embodiments of the technical ideas of the present disclosure.

FIG. 9 is a top view showing a wafer including a die alignment mark according to some embodiments of the technical ideas of the present disclosure.

FIG. 10 is a top view showing a semiconductor chip protection film including a film alignment mark according to some embodiments of the technical ideas of the present disclosure.

FIG. 11 is a top view showing a wafer including a die alignment mark according to some embodiments of the technical ideas of the present disclosure.

FIG. 12 is an enlarged view showing only a region A of FIG. 11.

FIG. 13 is a top view showing a semiconductor chip protection film including the film alignment mark according to some embodiments of the technical ideas of the present disclosure.

FIG. 14 is an enlarged view showing only a region B of FIG. 13.

FIG. 15 is an exploded perspective view for explaining a semiconductor chip unit according to some embodiments of the technical ideas of the present disclosure.

FIG. 16 is a top view for explaining a semiconductor chip unit according to some embodiments of the technical ideas of the present disclosure.

FIG. 17 is a cross-sectional view showing a cross section along III-III′ of FIG. 15 together to explain a semiconductor chip unit according to some embodiments of the technical ideas of the present disclosure.

FIGS. 18 to 22 are cross-sectional views for explaining a method for fabricating the semiconductor package according to some embodiments of the technical ideas of the present disclosure.

### DETAILED DESCRIPTION

Hereinafter, the embodiments of the present disclosure will be described in detail with reference to the accompanying drawings. The same reference numerals are used for the same components in the drawings, and the repeated description will not be provided.

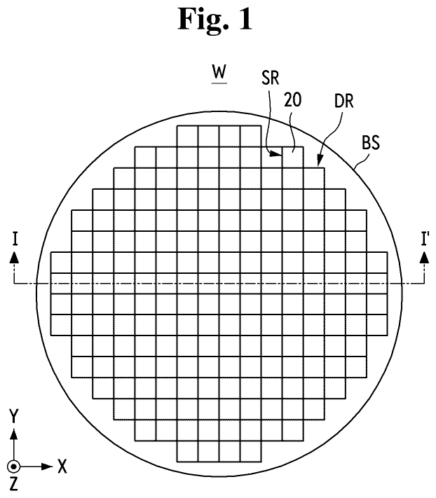

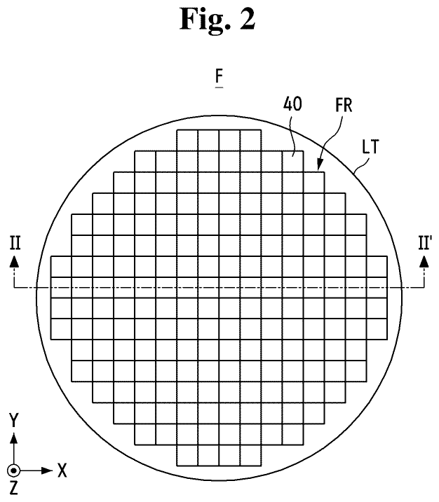

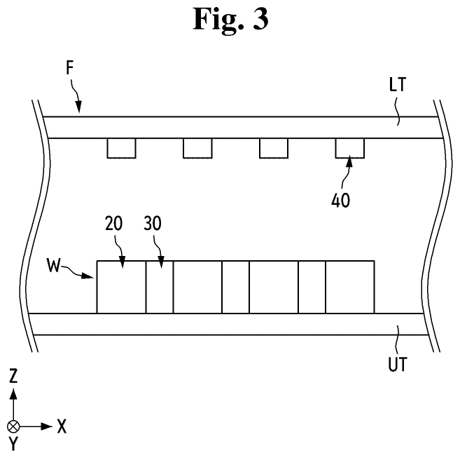

FIG. 1 is a top view showing a wafer including a semiconductor chip according to some embodiments of the technical ideas of the present disclosure. FIG. 2 is a top view showing a semiconductor chip protection film according to some embodiments of the technical ideas of the present disclosure. FIG. 3 is a cross-sectional view showing cross sections along I-I′ and II-II′ together to explain the semiconductor chip protection film and wafer of FIGS. 1 and 2.

Referring to FIG. 1, in some embodiments, the wafer W may include a base substrate BS. The base substrate BS may include a first side (or upper side) and a second side (or lower side) that are opposite to each other. The base substrate BS may have a circular plate shape.

In some embodiments, the wafer W may be a carrier substrate for performing a wafer level packaging (WLP) process.

The wafer W may include a plurality of regions that are individually divided on the first side of the base substrate BS. For example, the wafer W may include a die region (a package region) DR in which metal structures are formed, and a scribe lane region SR except the die region DR.

The die region DR may include a plurality of semiconductor chips 20 arranged along a plurality of rows and columns on the first side of the base substrate BS. For example, each of the plurality of rows may provide a row array in which some of the plurality of semiconductor chips 20 are arranged along a first direction X. Each of the plurality of columns may provide a column array in which some of the plurality of semiconductor chips 20 are arranged along a second direction Y that intersects the first direction X.

The scribe lane region SR may individually separate the plurality of semiconductor chips 20 on the first side of the base substrate BS.

Referring to FIG. 2, in some embodiments, the semiconductor chip protection film unit F may include a carrier LT. For example, the carrier LT may include a lamination tape LT. The carrier LT may include a first side (or an upper side) and a second side (or a lower side) that are opposite to each other. The carrier LT may have a circular plate shape.

The semiconductor chip protection film unit F may include a plurality of regions that are individually divided on the first side of the carrier LT. For example, the semiconductor chip protection film unit F may include a film region FR in which a plurality of sub-films are formed.

The semiconductor chip protection film unit F may include a plurality of semiconductor chip protection films 40 arranged along a plurality of rows and columns on the first side of the carrier LT. For example, each of the plurality of rows may provide a row array in which some of the plurality of semiconductor chip protection films 40 are arranged along the first direction X. Each of the plurality of columns may provide a column array in which some of the plurality of semiconductor chip protection films 40 are arranged along the second direction Y that intersects the first direction X.

In some embodiments, each of the plurality of semiconductor chip protection films 40 may be arranged to be spaced apart from each other on the first side of the carrier LT.

Referring to FIGS. 1 to 3, in some embodiments, each of the plurality of semiconductor chip protection films 40 may correspond to a plurality of semiconductor chips 20. For example, when the first side of the semiconductor chip protection film unit F and the first side of the wafer W are disposed to face each other, the semiconductor chip protection film 40 and the semiconductor chip 20 may face each other in a one-to-one correspondence.

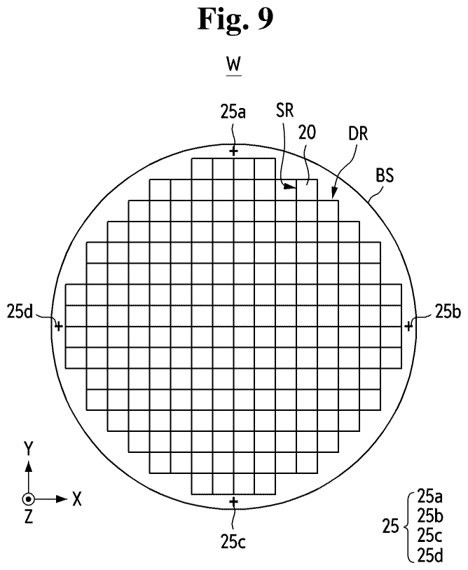

Each semiconductor chip protection film 40 may be attached to the corresponding semiconductor chip 20. The semiconductor chip protection film 40 may be attached to the semiconductor chip 20, thereby forming a semiconductor chip unit (CU of FIG. 9). Accordingly, the upper side of the semiconductor chip 20 may be protected. The configuration of the plurality of semiconductor chip protection films 40 and the plurality of semiconductor chips 20 and the specific formation process of the semiconductor chip unit CU will be described below.

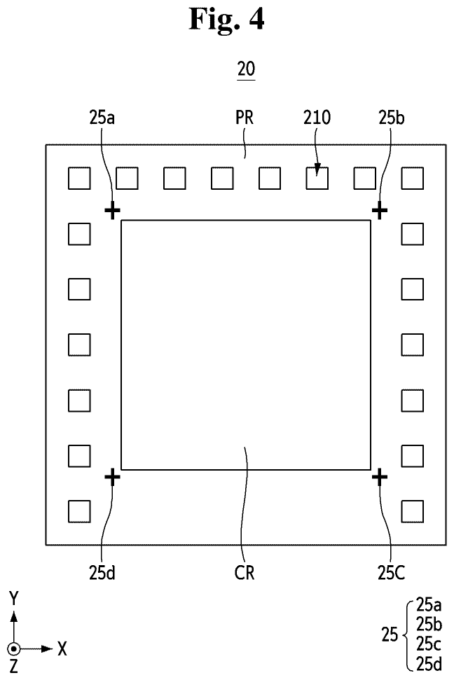

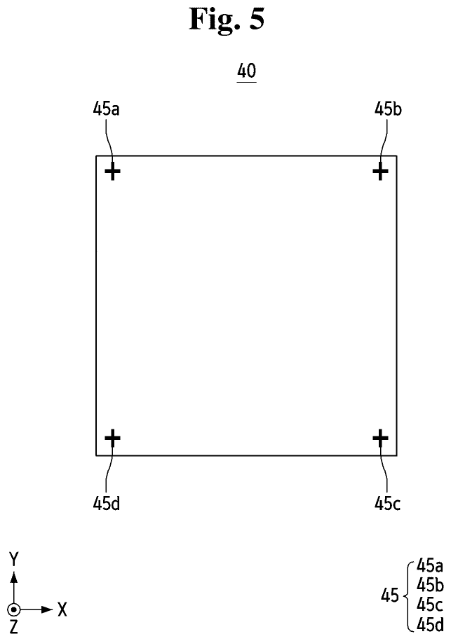

FIG. 4 is a top view showing only the semiconductor chip included in the die region of FIG. 2. FIG. 5 is a top view showing only the semiconductor chip protection film included in the film region of FIG. 1.

Referring to FIG. 4, the semiconductor chip 20 may include a sensor region CR and a pad region PR on the first side (or the upper side). For example, the semiconductor chip 20 may be an image sensor chip.

The sensor region CR may include a pixel array made up of plurality of unit pixels. The plurality of unit pixels may be arranged in the form of a two-dimensional array on the upper side of the semiconductor chip 20. The plurality of unit pixels may be active pixel sensors. Each of the plurality of unit pixels may include a photodiode for sensing light, a transfer transistor for transferring charges generated by the photodiode, a floating diffusion region for storing the transferred charges, a reset transistor for periodically resetting the floating diffusion region, a source buffer for buffering a signal according to the charges charged in the floating diffusion region, and the like. For example, the sensor region CR may include a CIS (CMOS image sensor) and a CCD (charge-coupled device).

A plurality of color filters and a plurality of microlenses disposed sequentially on the plurality of unit pixels may be disposed in the sensor region CR of the semiconductor chip 20. The plurality of color filters may include an R (red) filter, a B (blue) filter, and a G (green) filter. Alternatively, the plurality of color filters may include a C (cyan) filter, a Y (yellow) filter, and an M (magenta) filter. The plurality of microlenses may focus the light incident on the sensor region CR onto the unit pixels. Each of the plurality of unit pixels may sense components of the separated incident light and recognize one color.

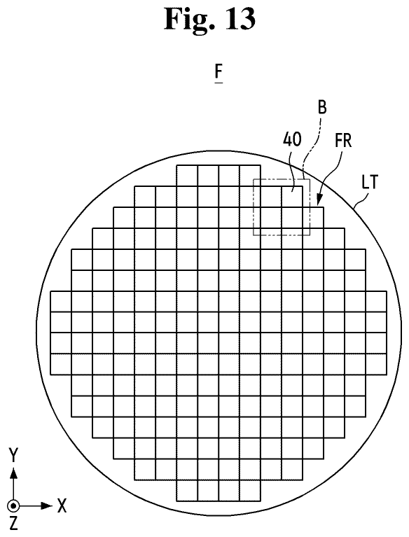

The pad region PR may include a plurality of bonding pads 210. The plurality of bonding pads 210 may electrically connect the semiconductor chip 20 to an external device through a wire (50 of FIG. 13).

The sensor region CR may be disposed at the center of the semiconductor chip 20. The pad region PR may surround the sensor region CR.

The semiconductor chip 20 may include a die alignment mark 25 on the first side (or the upper side).

The die alignment mark 25 may include a plurality of sub-die alignment marks 25a, 25b, 25c, and 25d. The die alignment mark 25 may be a marking for indicating a position and an angle at which the semiconductor chip protection film 40 is attached to the semiconductor chip 20. For example, the semiconductor chip protection film 40 may be attached to the sensor region CR of the semiconductor chip 20.

In some embodiments, the die alignment mark 25 may have any shape that allows the semiconductor chip protection film 40 to be properly aligned on the sensor region CR of the semiconductor chip 20. For example, the die alignment mark 25 may have a cross shape extending in each of the first direction X and the second direction Y.

Furthermore, in some embodiments, the die alignment mark 25 may be disposed in the pad region PR. For example, the die alignment mark 25 may be disposed between the sensor region CR and the bonding pad 210. However, embodiments of the present disclosure is not limited thereto, and it goes without saying that the die alignment mark 25 may be disposed at any position that allows the semiconductor chip protection film 40 to be properly aligned on the sensor region CR of the semiconductor chip 20.

In some embodiments, a plurality of sub-die alignment marks 25a, 25b, 25c, and 25d may be disposed at each vertex of the sensor region CR. For example, the die alignment mark 25 may include a first sub-die alignment mark 25a, a second sub-die alignment mark 25b, a third sub-die alignment mark 25c, and a fourth sub-die alignment mark 25d that are disposed at each vertex of the sensor region CR. However, embodiments of the present disclosure is not limited thereto, and it goes without saying that the die alignment mark 25 may be disposed at any position that allows the semiconductor chip protection film 40 to be properly aligned on the sensor region CR of the semiconductor chip 20.

Referring to FIG. 5, the semiconductor chip protection film 40 may include a film alignment mark 45 on the first side (or the upper side).

The film alignment mark 45 may include a plurality of sub-film alignment marks 45a, 45b, 45c, and 45d. The film alignment mark 45 may guide the attachment position of the semiconductor chip protection film 40 so that the semiconductor chip protection film 40 may be properly aligned on the sensor region CR of the semiconductor chip 20.

The film alignment mark 45 may be a marking corresponding to the die alignment mark 25. For example, the film alignment mark 45 may have the same shape as the die alignment mark 25. Accordingly, the position and angle may be aligned, when the semiconductor chip protection film 40 is attached to the semiconductor chip 20. However, embodiments of the present disclosure is not limited thereto, and it goes without saying that the film alignment mark 45 may have any shape that allows the semiconductor chip protection film 40 to be properly aligned on the sensor region CR of the semiconductor chip 20.

In some embodiments, the plurality of sub-film alignment marks 45a, 45b, 45c, and 45d may be disposed at each vertex of the semiconductor chip protection film 40. For example, the film alignment mark 45 may include a first sub-film alignment mark 45a, a second sub-film alignment mark 45b, a third sub-film alignment mark 45c, and a fourth sub-film alignment mark 45d that are disposed at each vertex of the semiconductor chip protection film 40. However, embodiments of the present disclosure is not limited thereto, and it goes without saying that the film alignment mark 45 may be disposed at any position that allows the semiconductor chip protection film 40 to be properly aligned on the sensor region CR of the semiconductor chip 20.

When the semiconductor chip protection film 40 is attached to the semiconductor chip 20, a first sub-die alignment mark 25a may overlap the first sub-film alignment mark 45a in the third direction Z. Similarly, a second sub-die alignment mark 25b may overlap the second sub-film alignment mark 45b in the third direction Z. A third sub-die alignment mark 25c may overlap the third sub-film alignment mark 45c in the third direction Z. A fourth sub-die alignment mark 25d may overlap the fourth sub-film alignment mark 45d in the third direction Z.

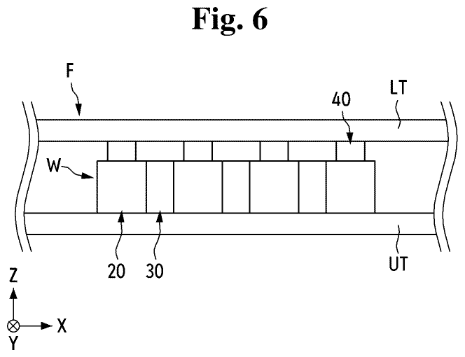

FIGS. 6 to 8 are cross-sectional views for explaining a method for fabricating a semiconductor chip unit according to some embodiments of the technical ideas of the present disclosure.

Referring to FIG. 6, when the first side of the semiconductor chip protection film unit F and the first side of the wafer W are disposed to face each other, each semiconductor chip protection film 40 may be attached to the corresponding semiconductor chip 20 to overlap in the third direction Z.

While the semiconductor chip protection film unit F is attached to the wafer W, the semiconductor chip protection film 40 may be aligned to the sensor region CR of the semiconductor chip 20 by the film alignment mark 45 and the die alignment mark 25 of the semiconductor chip 20. For example, in the case of the film alignment mark 45 and the die alignment mark 25 having the same shape, when the semiconductor chip protection film 40 is attached to the semiconductor chip 20, the film alignment mark 45 and the die alignment mark 25 may completely overlap in the third direction Z.

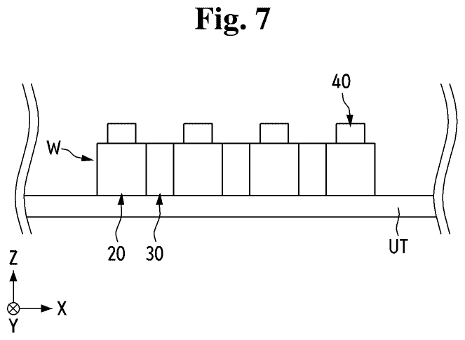

Referring to FIG. 7, after the semiconductor chip protection film 40 is attached to the semiconductor chip 20, the carrier LT may be removed.

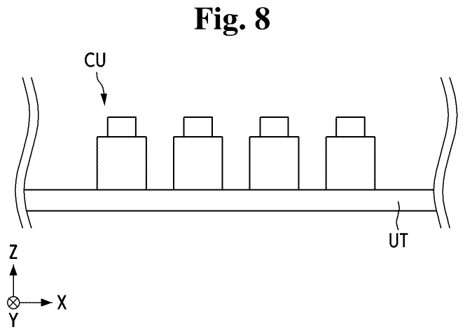

Referring to FIG. 8, the scribe lane region SR may be removed to form a plurality of semiconductor chip units CU.

According to the technical ideas of the present disclosure, at a wafer W cutting step for removing the scribe lane region SR, the upper side of the semiconductor chip 20 may be protected from foreign matter along the semiconductor chip protection film 40. Specifically, the sensor region CR of the semiconductor chip 20 may be protected. Accordingly, it is possible to prevent the residue of the wafer W from accumulating on the upper side of the semiconductor chip 20 at the cutting step. For example, the residue of the wafer W may include silicon (Si). The yield and productivity of the semiconductor chip 20 can be improved, accordingly.

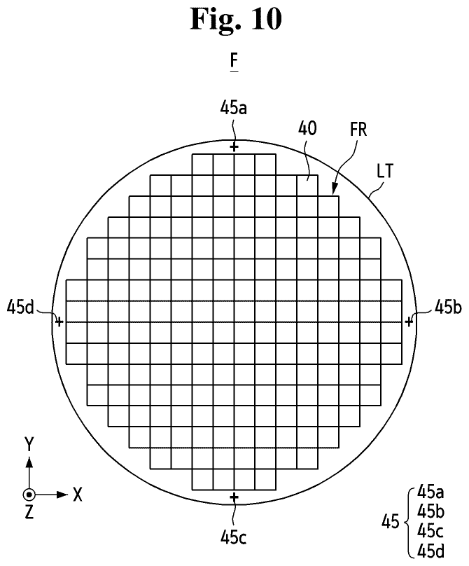

FIG. 9 is a top view showing a wafer including a die alignment mark according to some embodiments of the technical ideas of the present disclosure. FIG. 10 is a top view showing a semiconductor chip protection film including a film alignment mark according to some embodiments of the technical ideas of the present disclosure.

Referring to FIGS. 9 and 10, unlike that described through FIGS. 4 and 5, in some embodiments, the wafer W may include a die alignment mark 25 on the first side (or the upper side). For example, the die alignment mark 25 may be disposed along the outer periphery of the wafer W. However, embodiments of the present disclosure is not limited thereto, and it goes without saying that the die alignment mark 25 may be disposed at any position that allows the semiconductor chip protection film 40 to be properly aligned on the sensor region CR of the semiconductor chip 20.

The die alignment mark 25 may include a plurality of sub-die alignment marks 25a, 25b, 25c, and 25d. The die alignment mark 25 may be a marking for indicating the position and angle at which the semiconductor chip protection film 40 is attached to the semiconductor chip 20.

In some embodiments, the die alignment mark 25 may have any shape that allows the semiconductor chip protection film 40 to be properly aligned on the sensor region CR of the semiconductor chip 20. For example, the die alignment mark 25 may have a cross shape extending in each of the first direction X and the second direction Y.

In some embodiments, the semiconductor chip protection film unit F may include a film alignment mark 45 on the first side (or the upper side). For example, the film alignment mark 45 may be disposed along the outer periphery of the carrier LT. The film alignment mark 45 may guide the attachment position of the semiconductor chip protection film 40 so that the semiconductor chip protection film 40 is properly aligned on the sensor region CR of the semiconductor chip 20.

The film alignment mark 45 may include a plurality of sub-film alignment marks 45a, 45b, 45c, and 45d. The film alignment mark 45 may be a marking corresponding to the die alignment mark 25. For example, the film alignment mark 45 may have the same shape as the die alignment mark 25. Accordingly, the position and angle may be aligned when the semiconductor chip protection film 40 is attached to the semiconductor chip 20. However, embodiments of the present disclosure is not limited thereto, and it goes without saying that the film alignment mark 45 has any shape that allows the semiconductor chip protection film 40 to be properly aligned on the sensor region CR of the semiconductor chip 20.

When the semiconductor chip protection film 40 is attached to the semiconductor chip 20, the first sub-die alignment mark 25a may overlap the first sub-film alignment mark 45a in the third direction Z. Similarly, the second sub-die alignment mark 25b may overlap the second sub-film alignment mark 45b in the third direction Z. The third sub-die alignment mark 25c may overlap the third sub-film alignment mark 45c in the third direction Z. The fourth sub-die alignment mark 25d may overlap the fourth sub-film alignment mark 45d in the third direction Z.

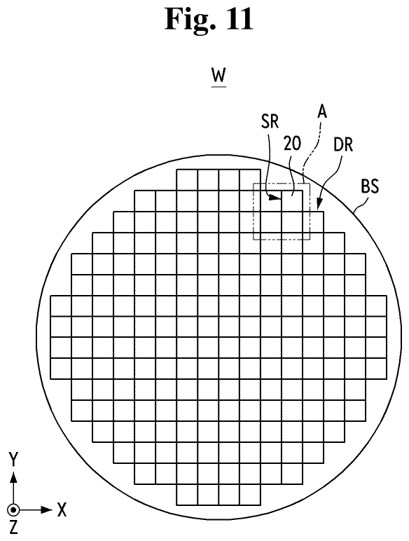

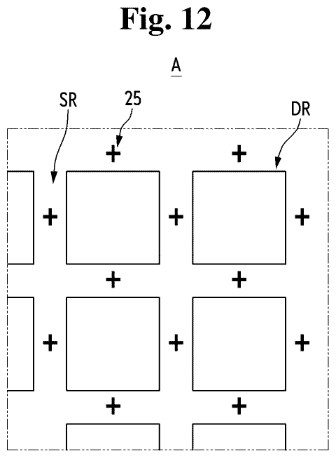

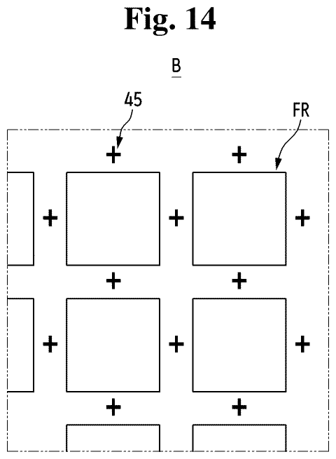

FIG. 11 is a top view showing a wafer including a die alignment mark according to some embodiments of the technical ideas of the present disclosure. FIG. 12 is an enlarged view showing only a region A of FIG. 11. FIG. 13 is a top view showing a semiconductor chip protection film including the film alignment mark according to some embodiments of the technical ideas of the present disclosure. FIG. 14 is an enlarged view showing only a region B of FIG. 13.

Referring to FIGS. 11 to 14, unlike those described through FIGS. 4 and 5, in some embodiments, the wafer W may include a die alignment mark 25 on the first side (or the upper side). For example, the die alignment mark 25 may be disposed in the scribe lane region SR between a plurality of semiconductor chips 20. However, embodiments of the present disclosure is not limited thereto, and it goes without saying that the die alignment mark 25 may be disposed at any position that allows the semiconductor chip protection film 40 to be properly aligned on the sensor region CR of the semiconductor chip 20.

The die alignment mark 25 may be a marking for indicating the position and angle at which the semiconductor chip protection film 40 is attached to the semiconductor chip 20.

In some embodiments, the die alignment mark 25 may have any shape that allows the semiconductor chip protection film 40 to be properly aligned on the sensor region CR of the semiconductor chip 20. For example, the die alignment mark 25 may have a cross shape extending in each of the first direction X and the second direction Y.

In some embodiments, the carrier LT may include a film alignment mark 45 on the first side (or the upper side). For example, the film alignment mark 45 may be disposed on the carrier LT between a plurality of semiconductor chip protection films 40. The film alignment mark 45 may guide the attachment position of the semiconductor chip protection film 40 so that the semiconductor chip protection film 40 may be properly aligned on the sensor region CR of the semiconductor chip 20.

The film alignment mark 45 may be a marking corresponding to the die alignment mark 25. For example, the film alignment mark 45 may have the same shape as the die alignment mark 25. Accordingly, the position and angle can be aligned when attaching the semiconductor chip protection film 40 to the semiconductor chip 20. However, embodiments of the present disclosure is not limited thereto, and it goes without saying that the film alignment mark 45 may have any shape that allows the semiconductor chip protection film 40 to be properly aligned on the sensor region CR of the semiconductor chip 20.

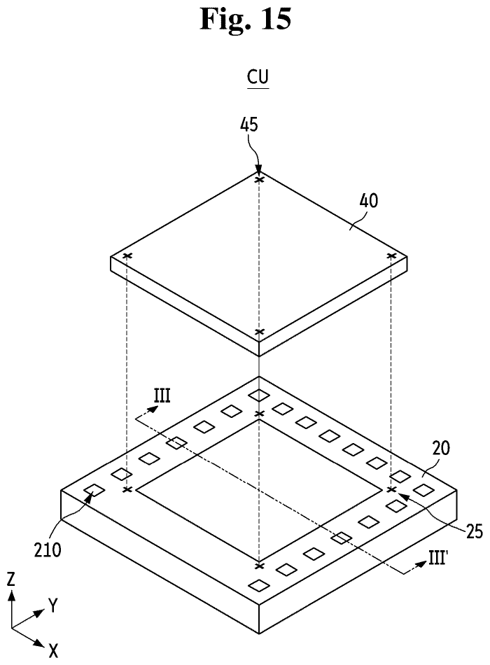

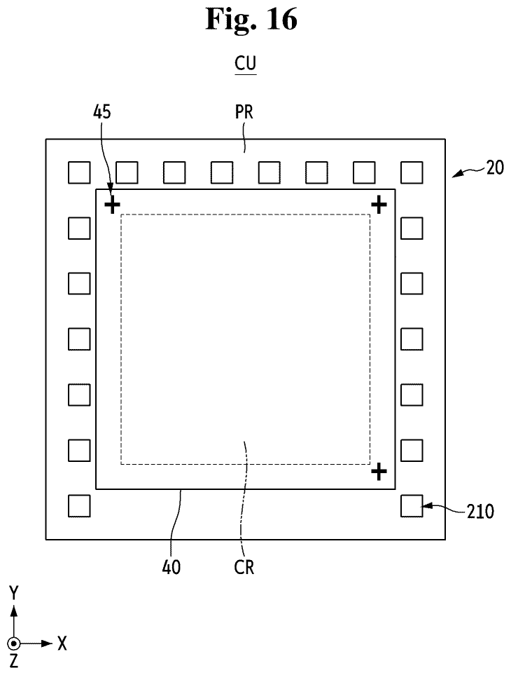

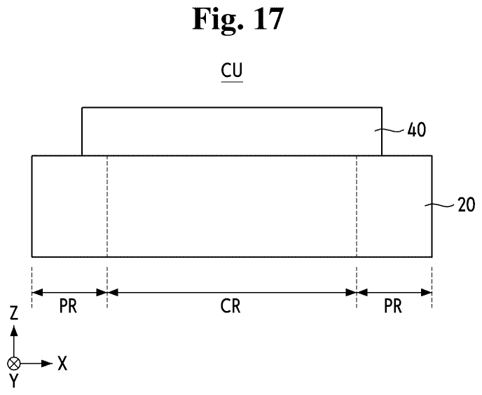

FIG. 15 is an exploded perspective view for explaining a semiconductor chip unit according to some embodiments of the technical ideas of the present disclosure. FIG. 16 is a top view for explaining a semiconductor chip unit according to some embodiments of the technical ideas of the present disclosure. FIG. 17 is a cross-sectional view showing a cross section along III-III′ of FIG. 15 together to explain a semiconductor chip unit according to some embodiments of the technical ideas of the present disclosure.

Referring to FIGS. 15 to 17, the semiconductor chip unit CU may include a semiconductor chip 20 and a semiconductor chip protection film 40. For example, the semiconductor chip 20 may be a CMOS image sensor.

In some embodiments, the semiconductor chip protection film 40 may be attached to the upper side of the semiconductor chip 20.

The film alignment mark 45 and the die alignment mark 25 of the semiconductor chip 20 may align the semiconductor chip protection film 40 in the sensor region CR of the semiconductor chip 20. For example, in the case of the film alignment mark 45 and the die alignment mark 25 having the same shape, when the semiconductor chip protection film 40 is attached to the semiconductor chip 20, the film alignment mark 45 and the die alignment mark 25 may completely overlap in the third direction Z.

Furthermore, in some embodiments, the die alignment mark 25 may be disposed in the pad region PR. For example, the die alignment mark 25 may be disposed between the sensor region CR and the bonding pad 210.

The area of the semiconductor chip protection film 40 may be smaller than or equal to the area of the semiconductor chip 20. Specifically, the semiconductor chip protection film 40 completely covers the sensor region CR of the semiconductor chip 20 in the third direction Z, and may not overlap the bonding pad 210. That is, the area of the semiconductor chip protection film 40 may be larger than the sensor region CR of the semiconductor chip 20, and may be smaller than or equal to that of the semiconductor chip 20.

Because the semiconductor chip protection film 40 covers the sensor region CR of the semiconductor chip 20, the sensor region CR may be protected from foreign matter in the series of processes in which the semiconductor chip unit CU to be described below is packaged on the substrate (10 of FIG. 12).

In addition, because the semiconductor chip protection film 40 exposes the bonding pad 210 of the semiconductor chip 20, wire bonding between the substrate 10 and the semiconductor chip 20 may be performed, while protecting the sensor region CR from foreign matter that may occur during the process.

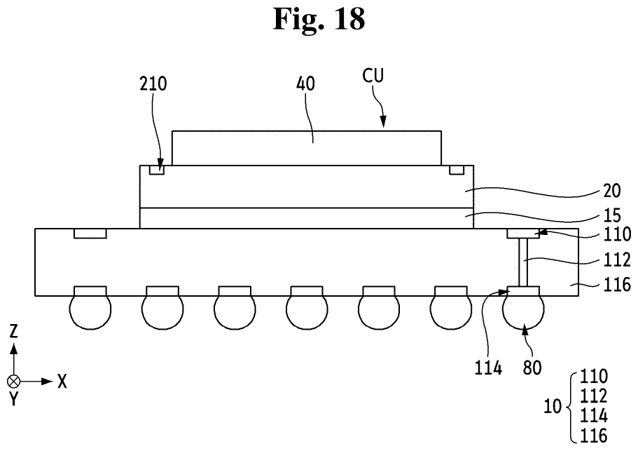

FIGS. 18 to 22 are cross-sectional views for explaining a method for fabricating the semiconductor package according to some embodiments of the technical ideas of the present disclosure.

Referring to FIG. 18, the semiconductor chip unit CU may be mounted on the substrate 10.

The substrate 10 may be, for example, a printed circuit board (PCB). The substrate 10 may include a substrate base 116 including at least one selected from phenolic resin, epoxy resin, and polyimide. The substrate 10 may also include an upper substrate pad 110 disposed on an upper side of the substrate base 116, and a lower substrate pad 114 disposed on a lower side of the substrate base 116. An internal wiring pattern 112 that electrically connects the upper substrate pad 110 and the lower substrate pad 114 may be disposed inside the substrate base 116. Although not shown, the substrate 10 may further include an upper passivation layer that covers the upper side of the substrate base 116 but exposes the upper substrate pad 110, and a lower passivation layer that covers the lower side of the substrate base 116 but exposes the lower substrate pad 114.

For example, each of the upper substrate pad 110 and the lower substrate pad 114 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga) and ruthenium (Ru), or a combination thereof.

The upper substrate pad 110 may be a portion into which a conductive connecting member for electrically connecting the substrate 10 and the semiconductor chip 20 is brought into contact.

The lower substrate pad 114 may be a portion to which an external connecting terminal 80 is attached. The external connecting terminal 80 may be connected to the lower substrate pad 114 through the opening of the lower passivation layer. The external connecting terminal 80 may be, for example, a solder ball. The external connecting terminal 80 may electrically connect between the semiconductor package and an external device (not shown).

The semiconductor chip unit CU may be attached to the substrate 10 by a first bonding member 15. In some embodiments, the first bonding member 15 may entirely come into contact with the lower side of the semiconductor chip unit CU. For example, the first bonding member 15 may be a thermal grease, a thermal pad or a die attach film.

In this manner, the semiconductor chip protection film 40 covers the sensor region CR of the semiconductor chip 20, thereby protecting the sensor region CR from foreign matter generated in a die attach process of mounting the semiconductor chip unit CU on the substrate 10. The yield and productivity of the semiconductor package can be improved, accordingly.

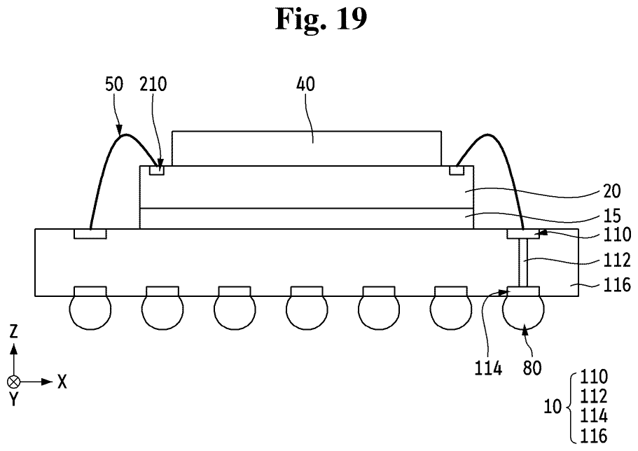

Referring to FIG. 19, the substrate 10 and the semiconductor chip 20 may be electrically connected to each other through the wire 50. For example, the wire 50 may extend between the upper substrate pad 110 of the substrate 10 and the bonding pad 210 of the semiconductor chip 20, and electrically connect the bonding pad 210 of the semiconductor chip 20 and the upper substrate pad 110 of the substrate 10.

At least one of a control signal, a power signal, and a ground signal for operating the semiconductor chip 20 may be provided from the outside through the wire 50. In addition, the data signal of the semiconductor chip 20 may be received from the outside through the wire 50, or the data signal of the semiconductor chip 20 may be provided to the outside. The material forming the wire 50 may include at least one of gold (Au), silver (Ag), copper (Cu), and aluminum (Al).

In some embodiments, the wire 50 may be connected by any one method of a thermos-compression connection and an ultrasonic connection, or may be connected by a thermos-sonic connection method that is a mixed method of the thermos-compression connection method and the ultrasonic connection method.

In this manner, since the semiconductor chip protection film 40 covers the sensor region CR of the semiconductor chip 20, the sensor region CR may be protected from foreign matter generated in the wire bonding process of electrically connecting the semiconductor chip unit CU and the substrate 10. The yield and productivity of the semiconductor package can be improved, accordingly.

In addition, since the semiconductor chip protection film 40 exposes the bonding pads 210 of the semiconductor chip 20, wire bonding between the substrate 10 and the semiconductor chip 20 may be performed, while protecting the sensor region CR from foreign matter that may occur during the wire bonding process.

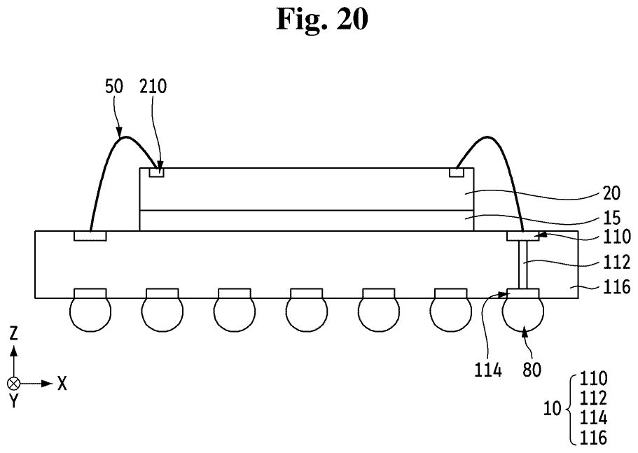

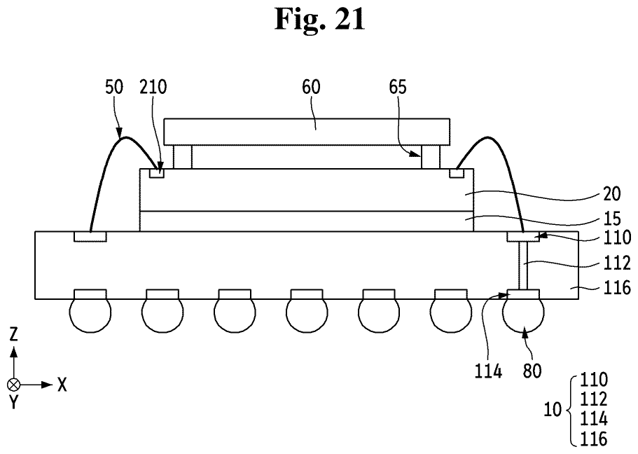

Referring to FIGS. 20 and 21, the semiconductor chip protection film 40 disposed on the semiconductor chip 20 may be removed. Further, a cover glass 60 may be disposed on the semiconductor chip 20 from which the semiconductor chip protection film 40 is removed.

The cover glass 40 may be attached to the second bonding member 65 and disposed on the semiconductor chip 20. The cover glass 40 may include a material having a high light transmittance. For example, the cover glass 40 may include a transparent glass or a transparent polymer. In some embodiments, the cover glass 40 may further include a filter for passing or blocking light of a specific wavelength band. For example, the second bonding member 65 may be a thermal grease, a thermal pad or a die attach film.

That is, the semiconductor chip protection film 40 is attached to the semiconductor chip 20 until immediately before the cover glass 60 that protects the sensor region (CR of FIG. 4) of the semiconductor chip 20 is disposed, and may protect the sensor region CR of the semiconductor chip 20 from foreign matter that may occur at the wafer level and package level.

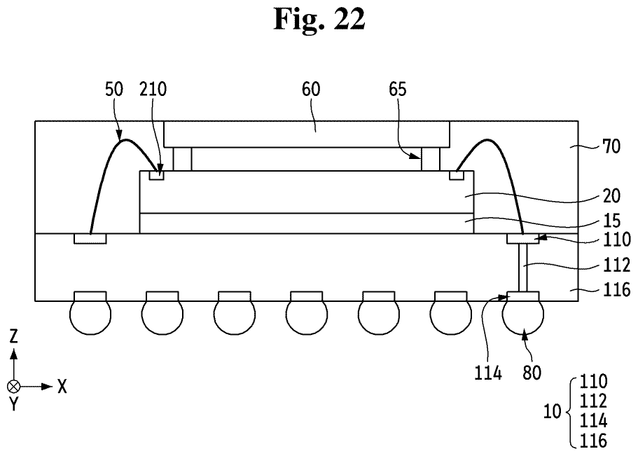

Referring to FIG. 22, a sealing material 70 that seals the substrate 10, the semiconductor chip 20, and the cover glass 60 may be filled. Specifically, the sealing material 50 may be formed to cover the side face of the semiconductor chip 20 and the side face of the cover glass 40. The sealing material 50 may not cover the upper side of the cover glass 40 so that the upper side of the cover glass 40 may be exposed.

For example, the sealing material 50 may be formed by injecting an insulating resin onto the substrate 10 and curing the insulating resin. While the sealing material 50 is being formed, the second bonding member 65 may prevent the material that constitutes the sealing material 50 from entering the internal space between the second bonding member 65 and the cover glass 40. Accordingly, it is possible to prevent the sealing material 50 from being filled between the sensor region CR and the cover glass 40. The sealing material 50 may include epoxy molding resin, polyimide molding resin, or the like. For example, the sealing material 50 may include epoxy molding compound (EMC).

According to the semiconductor chip 20, the semiconductor chip protection film 40, the semiconductor chip unit CU, and the semiconductor package according to the technical ideas of the present disclosure, each of the semiconductor chip 20 and the semiconductor chip protection film 40 may include the die alignment mark 25 and the film alignment mark 45. By including the die alignment mark 25 and the film alignment mark 45, the semiconductor chip protection film 40 may be accurately aligned on the sensor region CR of the semiconductor chip 20. Accordingly, it is possible to protect the sensor region CR from the foreign matter in the cutting step of the wafer W and the series of processes of packaging the semiconductor chip unit CU on the substrate 10, and improve the yield and productivity of the semiconductor package.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor chip protection film comprising:
a plurality of sub-films which are attached to a wafer; and
a carrier which carries the plurality of sub-films,
wherein at least one of the sub-films and the carrier includes a film alignment mark on an upper side,
the wafer has a die alignment mark on an upper side,
the sub-films are attached at a first position on the wafer, and
the first position is a position at which the film alignment mark and the die alignment mark overlap in a first direction.

2. The semiconductor chip protection film of claim 1, wherein:
the wafer includes a plurality of semiconductor chips, and
an area of the sub-film is smaller than or equal to an area of the semiconductor chips.

3. The semiconductor chip protection film of claim 2,
wherein:
the semiconductor chip includes:
a sensor region, and
a pad region which surrounds the sensor region and on which a plurality of bonding pads for connecting the semiconductor chip to the outside are disposed,
the sub-film covers the sensor region, and
an area of the sub-film is greater than or equal to an area of the sensor region.

4. The semiconductor chip protection film of claim 3,
wherein the sensor region includes an active pixel sensor.

5. The semiconductor chip protection film of claim 3,
wherein:
the die alignment mark is included on the pad region, and
the film alignment mark is included on the sub-film.

6. The semiconductor chip protection film of claim 3,
wherein the sub-film does not overlap the bonding pad in the first direction.

7. The semiconductor chip protection film of claim 1,
wherein the film alignment mark is disposed on the carrier.

8. The semiconductor chip protection film of claim 7,
wherein the die alignment mark is disposed along an outer periphery of the wafer.

9. The semiconductor chip protection film of claim 7,
wherein the die alignment mark is disposed between a plurality of semiconductor chips included in the wafer.

10. The semiconductor chip protection film of claim 1,
wherein the carrier is removed with the sub-film located at the first position.

11. A semiconductor chip protection film which is attached to a semiconductor chip, and includes a film alignment mark on an upper side,
wherein:
the semiconductor chip has a die alignment mark on an upper side, and
the film alignment mark and the die alignment mark overlap in a first direction.

12. The semiconductor chip protection film of claim 11,
wherein an area of the semiconductor chip protection film is smaller than or equal to an area of the semiconductor chip.

13. The semiconductor chip protection film of claim 11,
wherein:
the semiconductor chip includes:
a sensor region, and
a pad region which surrounds the sensor region and on which a plurality of bonding pads for connecting the semiconductor chip to the outside are disposed,
the semiconductor chip protection film covers the sensor region, and
an area of the semiconductor chip protection film is greater than or equal to an area of the sensor region.

14. The semiconductor chip protection film of claim 13,
wherein the sensor region includes an active pixel sensor.

15. The semiconductor chip protection film of claim 13,
wherein the die alignment mark is included on the pad region.

16. The semiconductor chip protection film of claim 13,
wherein the semiconductor chip protection film does not overlap the bonding pad in the first direction.

17. A semiconductor chip protection film comprising:
a plurality of sub-films which are attached to a wafer including a plurality of semiconductor chips; and
a carrier which carries the plurality of sub-films,
wherein:
the carrier includes a film alignment mark on an upper side,
the wafer has a die alignment mark on an upper side, and
the film alignment mark and the die alignment mark overlap in the first direction.

18. The semiconductor chip protection film of claim 17,
wherein the die alignment mark is disposed along the outer periphery of the wafer.

19. The semiconductor chip protection film of claim 17,
wherein the die alignment mark is disposed between the plurality of semiconductor chips.

20. The semiconductor chip protection film of claim 17,
wherein the carrier is removed after the sub-film is attached to the semiconductor chip.
